(19) United States
(12) Patent Application Publication
(10) Pub. No.: US 2013/0028829 A1
(43) Pub. Date: Jan. 31, 2013

(54) SYSTEM AND METHOD FOR GROWTH OF ENHANCED ADHESION CARBON NANOTUBES ON SUBSTRATES

(71) Applicants: John G. Hagopian, Harwood, MD (US); Stephanie A. Getty, Washington, DC (US); Manuel A. Quijada, Laurel, MD (US)

(72) Inventors: John G. Hagopian, Harwood, MD (US); Stephanie A. Getty, Washington, DC (US); Manuel A. Quijada, Laurel, MD (US)

(21) Appl. No.: 13/193,272

(22) Filed: Jul. 28, 2011

(51) Int. Cl. C23C 16/26; D01F 9/12; B82Y 40/00; B82Y 99/00

(52) U.S. Cl. 423/447.2; 427/255.28; 216/67; 216/64; 977/752; 977/843

(57) ABSTRACT

Disclosed herein is a method of growth of enhanced adhesion MWCNTs on a substrate, referred to as the HGTiE process, the method comprising: chemical vapor deposition of an adhesive underlayer composed of alumina on a substrate composed of titanium or similar; chemical vapor deposition of a catalyst such as a thin film of iron on top of the adhesive underlayer; pretreatment of the substrate to hydrogen at high temperature; and exposure of the substrate to a feedstock gas such as ethylene at high temperature. The substrate surface may be roughened before placement of an adhesive layer through mechanical grinding or chemical etching. Finally, plasma etching of the MWCNT film may be performed with oxygen plasma. This method of growth allows for high strength adhesion of MWCNTs to the substrate the MWCNTs are grown upon.

### ORIGIN OF THE INVENTION

The invention described herein was made by employees of the United States Government. It may be manufactured and used by or for the Government for governmental purposes without payment of any royalty thereon or therefor.

### BACKGROUND OF THE INVENTION

A. Technical Field

The present disclosure relates to the growth of robust multiwalled carbon nanotubes with enhanced adhesion properties on substrates such as titanium, stainless steel, silicon nitride and silicon.

B. Introduction

Carbon nanotubes (CNTs) are allotropes of carbon with a cylindrical structure. Multiwalled carbon nanotubes (MWCNTs) comprise of multiple CNTs wrapped around each other and have many useful properties, including the ability to absorb light over all angles, including grazing angles, when compared to conventional means of light absorption, such as black paint. Another useful property of MWCNTs is efficient absorption of light for detection, such as absorption of infrared light to measure temperature. The development of MWCNTs in these areas of research and others has been limited due to the lack of MWCNTs' adhesion to the surface upon which they are grown (known as a substrate), leaving MWCNT growths too weak for use in demanding environments such as launch and spaceflight. Many current methods of growth have led to the micro-fabrication of MWCNTs with such minimal adhesion properties that can be easily wiped off the substrate upon which they are grown with a light brush of a human finger.

MWCNTs are widely grown in many forms and on various substrates. Creating a growth of MWCNTs, such that both the MWCNTs and the substrate the MWCNTs have been grown upon can withstand abrasion and shock, has proven challenging. Furthermore, many substrates that MWCNTs are grown upon are not suitable for use as structural materials in demanding environments, such as silicon, and this problem has not been addressed in the prior art. Accordingly, what is needed in the art is a method of growth for MWCNTs grown upon a structurally suitable substrate wherein the MWCNTs have enhanced adhesion to the substrate upon which they are grown.

### BRIEF DESCRIPTION OF THE INVENTION

Disclosed herein is a method of growth of enhanced adhesion MWCNTs on a substrate, the method comprising: an alumina adhesive layer applied to the substrate, an iron thin film catalyst layer applied to the adhesive layer, and exposure of the substrate to a feedstock gas. The substrate surface may be roughened before placement of an adhesive layer through mechanical grinding or chemical etching. Finally, plasma etching of the MWCNT film may be performed with oxygen plasma.

### DESCRIPTION OF THE DRAWINGS

In order to describe the manner in which the above-recited and other advantages and features of the disclosure may be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1 illustrates the method in the form of a flow chart;

FIG. 2 illustrates an example growth pattern of MWCNTs on a silicon substrate with an alumina adhesive underlayer;

FIG. 3 illustrates an example growth pattern of MWCNTs on a titanium substrate;

FIG. 4 illustrates the effect of surface treatment using plasma etching;

FIG. 5 illustrates an exemplary apodization mask shape;

FIGS. 6, 7 and 8 illustrate charts based on ray trace code modeling of irradiance measurements of stray light emitted by various light absorptive materials;

FIG. 9 illustrates a sample image of ocean chlorophyll concentration displaying the effects of stray light contamination in remote sensing instruments; and

FIG. 10 illustrates an example system embodiment of a duplex telescope.

FIG. 11 illustrates a Multiwalled Carbon Nanotube Hemispherical Reflectance Vs Lords Aeroglaze of an embodiment of the present invention.

FIG. 12 illustrates a BRDF of MWCNTs at 500 nm wavelength.

FIG. 13 illustrates another BRDF of MWCNTs at 500 nm wavelength.

FIG. 14 illustrates a Multiwalled Carbon Nanotube Reflectance on Ti and Si Substrates.

FIG. 15 illustrates Specular Reflectance for Verticall Oriented and Randomly Oriented Carbon Walled Nanotubes.

FIG. 16 illustrates an example of Vertically Aligned Carbon Nanotube Reflectance.

FIG. 17 illustrates a Comparison of Circular Mask of MWCNTs.

FIG. 18 illustrates a Comparison of Fresnel Pattern (Apodization) Mask of MWCNTs.

FIG. 19 illustrates an example of a Intensity Reduction with Apodization Mask.

FIG. 20 illustrates an example of a Carbon Nanotubes TI enhanced MWCNT.

### DETAILED DESCRIPTION OF THE INVENTION

### A. Background Science of the Invention

The following is written for illustration pursuant to 35 USC §112 for disclosing the best mode currently contemplated by the inventors. While specific implementations are discussed, it should be understood that this is done for illustration purposes only. A person skilled in the relevant art will recognize that other components and configurations may be used without parting from the spirit and scope of the disclosure.

1. Multiwalled Carbon Nanotubes as Light-Absorptive Material

There are many applications for MWCNTs in industry due to their useful properties. For example, MWCNTs are exceptionally good absorbers of light, including light striking at grazing angles, when compared to conventional means of light absorption, such as black paint. Furthermore, the potential of MWCNTs provides significant improvement over current surface treatments, and a large resulting reduction in stray light when applied to an entire optical train. Development of this technology may provide numerous benefits including: (1) simplification of instrument stray light controls to achieve equivalent performance, (2) increasing observational efficiencies by recovering currently unusable scenes in high contrast regions, and (3) enabling low-noise observations that are beyond current capabilities.

2. Use of Invention in LISA

One application of the best mode currently contemplated for the invention is in employment of NASA's LISA mission. LISA is planned to be a group of three satellites, each satellite composed of two duplex telescopes (making a total of six duplex telescopes). The LISA satellites are planned to be deployed in an equilateral triangle formation orbiting around the sun, with each satellite approximately five million kilometers apart from the other two. As gravitational waves from distant sources reach LISA, they warp space-time, stretching and compressing the triangle. Thus, by precisely monitoring the separation between the spacecraft (by measuring distance with LISA's built-in duplex telescopes), the waves may in turn be measured. By studying the shape and timing of the waves NASA may learn about the nature and evolution of the systems that emitted them.

Due to the nature of duplex telescopes, the secondary mirror of a duplex telescope is often a troublesome area where the transmitted signal emitted by the duplex telescope is reflected off of the secondary mirror, but a small portion of that reflected light may be erroneously sent back into the duplex telescope's own receiver, effectively blinding itself. Even a fraction of the strong outgoing transmitted signal can cause the sensitive duplex telescope receiver to be saturated and misinterpret distant, weak incoming communication signals. It is contemplated that light absorbing enhanced adhesion MWCNTs applied to troublesome reflective areas, including but not limited to, the secondary mirror, may suppress unwanted stray light and mitigate this interference.

### B. HGTiE Process: Recipe for Enhanced Adhesion MWCNTs

A desirable feature of MWCNTs missing from prior art applications is the ability of MWCNTs to adhere to the substrate upon which they are grown, such that MWCNT growths are not lost or rendered inoperable because of adverse environmental factors. The present invention demonstrates a process for growth of MWCNTs with enhanced adhesion properties. This process, called Hagopian/Getty Titanium Enhanced (HGTiE), allows for a robust coating of MWCNTs to be grown on preferred substrates such as those made of titanium, stainless steel, silicon nitride or silicon and remain attached to the substrate under greater shock and abrasion than previously possible.

The HGTiE process for enhanced adhesion MWCNTs is as follows.

1. Substrate Cleaning

Those of skill in the relevant art will recognize that a standard solvent clean in the micro-fabrication industry involves cleaning a substrate in solvents and water. Those skilled in the relevant art will also realize the importance of limiting particulates and other contaminants on a substrate before use in micro-fabrication. A substrate may undergo a standard solvent clean in (1) acetone, then (2) either isopropanol or ethanol, and then (3) water.

2. Chemical Vapor Deposition in Evaporation Chamber

Evaporation may take place in a Kurt J. Lester Company PVD 75™ Physical Vapor Deposition/Evaporation Chamber (evaporation chamber) or equivalent. Evaporation may begin by reducing the base pressure of the evaporation chamber to less than approximately 2 microTorr. A preferred method of evaporation is electron beam evaporation, although those skilled in the relevant art will recognize that other means of evaporation may be employed, including but not limited to, resistive evaporation, sputtering and pulsed laser deposition.

a. CVD of Adhesive Layer

Evaporation of alumina may then commence with evaporation of a preferred embodiment of 60 nanometers of high purity alumina at a preferred rate of 100 picometers per second. Those skilled in the relevant art will recognize that the amount of adhesive material necessary for evaporation varies with the surface area of the substrate targeted for deposition. Those skilled in the relevant art will also realize that the purpose of CVD, as related to adhesion, is to deposit a layer of vaporized material thick enough for adhesion to occur during the growth process of MWCNTs.

b. CVD of Catalyst Layer

The evaporation process may continue with evaporation of a preferred embodiment of 2 to 6 nanometers of high purity iron at a preferred rate of 80 picometers per second, depending on desired nanotube length. Those skilled in the relevant art will recognize that the amount of catalyst necessary for evaporation varies with the surface area of the substrate targeted for deposition. Furthermore, those skilled in the relevant art will also realize that the purpose of CVD, as related to catalysis, is to deposit a layer of catalyst material thick enough for catalysis to occur during the growth process of MWCNTs. Finally, those skilled in the relevant art will realize that the use of a thinner catalyst may contribute to longer MWCNTs (i.e., MWCNTs with a greater length to diameter ratio).

3. Hydrogen Pretreatment and MWCNT Growth in Furnace

Growth of MWCNTs may take place in a Lindberg/MPH Thermal Products Solutions Blue-M 36-inch 1200 degrees Celsius (° C.) Small Tube 3-Zone Furnace with an attached quartz process tube (quartz tube furnace) or equivalent. Growth may take place in any zone of the quartz tube furnace. The growth process may begin with the quartz tube furnace stable at atmospheric pressure at room temperature.

a. Furnace Purgation Process

A preferred gas choice for purgation of the furnace is argon, although those skilled in the art will recognize that other means of purgation may be employed, including but not limited to, nitrogen and other gases. A person skilled in the relevant art will also realize that the purpose of purging a furnace for micro-fabrication use includes but is not limited to, the removal of oxygen from the furnace. Growth may begin by purging the quartz tube furnace with flowing ultra-high purity argon at a preferred amount of 800 cubic centimeters per minute (ccm) for a preferred duration of 20 minutes. Argon used in the furnace may be introduced into the furnace by means of a water bubbler, which may force introduced gases through deionized water. The quartz tube furnace may then be heated to 750° C. at a preferred rate of 50° C. per minute under flowing argon at a preferred rate of 800 ccm. Those skilled in the relevant art will realize that the rate of heating the furnace may vary somewhat without significant impact to the MWCNT growth process.

b. Hydrogen Pretreatment Process

Hydrogen pretreatment may then occur, beginning with stabilization of the temperature of the quartz tube furnace at 750° C., followed by the introduction of ultra-high purity hydrogen inserted directly into the furnace at a preferred amount of 2000 ccm. Those skilled in the relevant art will realize that hydrogen pretreat process times may be varied from the standard of five minutes before the introduction of the ethylene feedstock gas up to five minutes after the feedstock gas has been introduced. Those skilled in the relevant art will further realize that the density and length of MWCNTs will vary depending upon the duration of hydrogen pretreatment employed as well as the composition of the substrate used. A preferred moment in time for introduction of hydrogen for silicon and silicon nitride substrates is five minutes after the introduction of the feedstock gas (T+5). A preferred moment in time for the introduction of hydrogen for both titanium and stainless steel substrates is five minutes before the introduction of the feedstock gas (T−5).

c. Feedstock Gas Introduction

Growth of MWCNTs may then occur using CVD with the introduction of a ultra-high purity ethylene feedstock gas at a preferred amount of 500 ccm and flowing argon at a preferred amount of 300 ccm. Those skilled in the relevant art will further realize that variations on growth also include, but are not limited to, reducing feedstock gas flow to control density of nanotubes from 30 seconds up to 15 minutes. Those skilled in the relevant art will also realize that if an insufficient amount of feedstock gas is introduced, MWCNTs are unlikely to form in useful amounts or geometries. Furthermore, those skilled in the relevant art will realize that if an excessive amount of feedstock gas is introduced, any one or more scenarios may result, including but not limited to, the forming of an amorphous carbon shell on the substrate, the failure of additional MWCNTs formation, and the loss of catalysis. Finally, the growth process may be completed by reducing the furnace temperature to room temperature in flowing argon at a preferred amount of 300 ccm to 800 ccm.

### C. Methodology for Growth and Optimization of Enhanced Adhesion MWCNTs for Use in Stray Light Suppression Applications

1. Stray Light Interference in Optical Sensing Instruments

The problem of stray light interference in optical sensing instruments has historically been compensated through the application of black paint on reflective areas such as mirrors, apertures, baffles, vanes and scan cavities. Such paint may include (1) LORD Aeroglaze® Z306 (Z306), (2) N-Science Corporation/Advanced Surface Technologies Optical Surfaces Deep Space Black™ (Deep Space Black) and (3) Infrared Coatings, Inc. Magic Black (Magic Black).

At grazing angles however, even the darkest paint becomes reflective, requiring the introduction of multiple baffles, stops and other means of light suppression to control stray light. In sum, black paint still allows scattering of light in telescopes, preventing the performance levels needed in highly sensitive laser transmissions such as in LISA.

2. Substrates for MWCNT Growth

In order to achieve growth of MWCNTs, an initial structural substrate may be used as a foundation for MWCNTs to be grown upon. Enhanced adhesion MWCNTs on a silicon substrate yield excellent light-absorptive ability. However, titanium and stainless steel are preferred embodiments for applications in which the substrate must withstand structural loads, and may be used as substrate materials for the enhanced adhesion process. Using titanium and stainless steel is beneficial since they are more suited as use as a structural element than silicon, perform well in high-temperature environments, are lightweight, and also allow for growth of light-absorptive, enhanced adhesion MWCNTs. When these preferred embodiments are used as substrates for HGTiE growth process of enhanced adhesion MWCNTs, they may retain a comparable light-absorptive ability to MWCNTs grown on silicon. Another preferred embodiment is contemplated using silicon nitride as a substrate using the HGTiE growth process for use in detector applications.

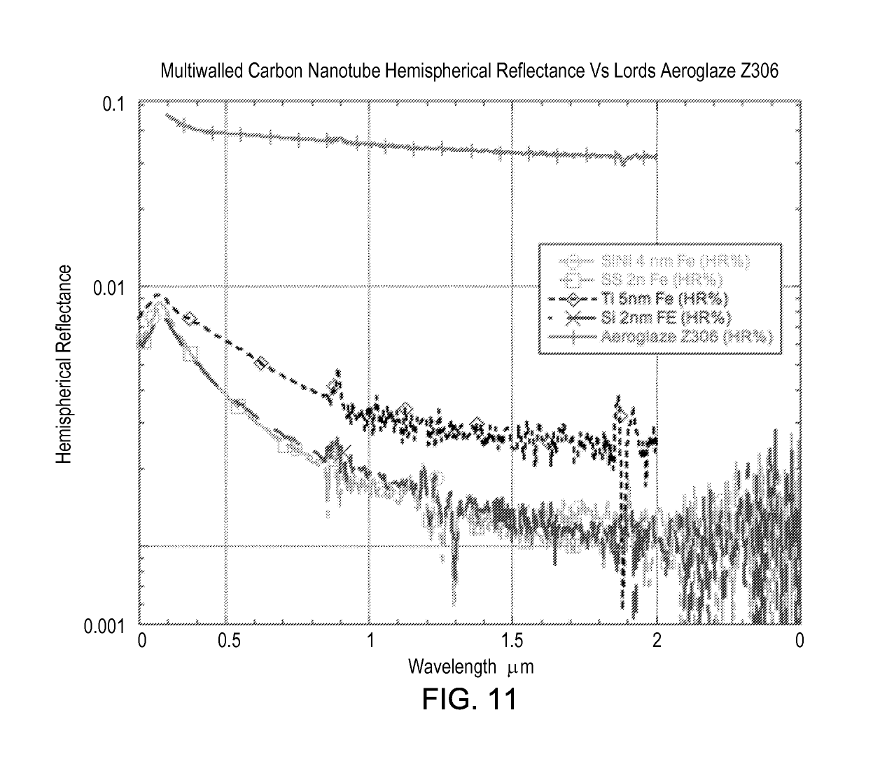

Hemispherical reflectance, also known as Total Integrated Scatter (TIS), is a measure of reflected light over pi steradians when light hits a sample. Hemispherical reflectance measurements of enhanced adhesion MWCNTs, according to the invention, are shown in FIG. 11, as performed in a Perkin Elmer Reflectometer using Z306 as a reference.

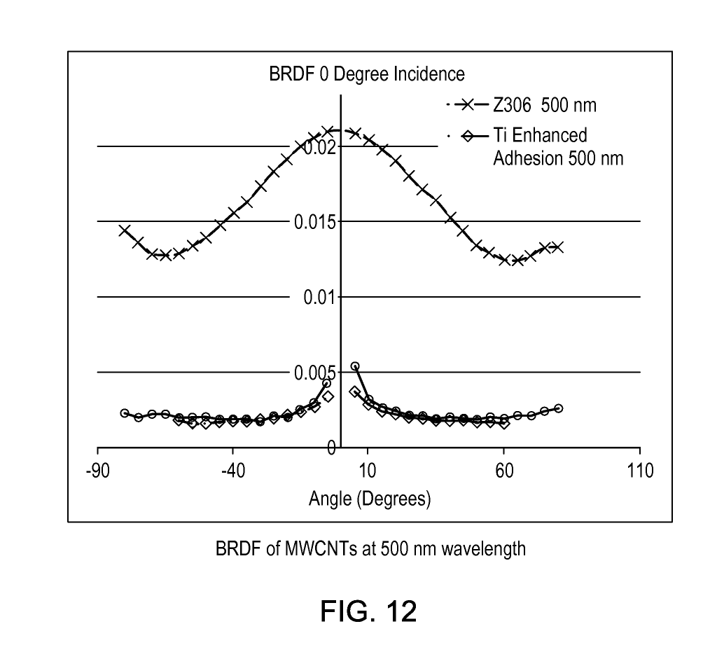

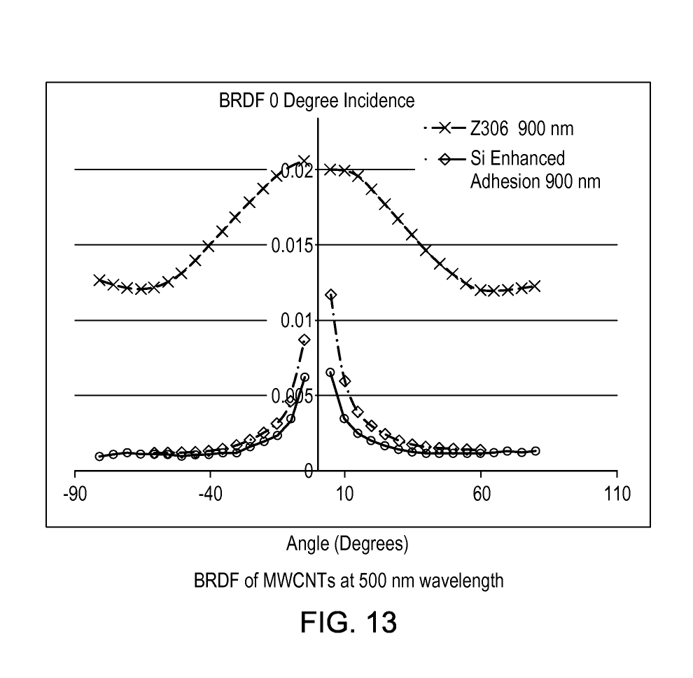

Bidirectional Reflectance Distribution Functions (BRDFs) allow for the measurement of reflectance as a function of angle. BRDF measurements of enhanced adhesion MWCNTs on titanium and silicon are shown in FIG. 12 and FIG. 13. Again, Z306 paint is used as a reference material in each chart.

3. Substrate Surface Roughness

Roughening the substrate surface with mechanical or other means of grinding may yield improvements in the light absorptive properties of the MWCNTs. Substrate roughening should be done prior to catalyst and adhesive deposition, and MWCNT film growth.

4. Catalyst Film Sublayer

The use of a catalyst, such as an aluminum/iron thin film catalyst, assists in the growth of MWCNTs. The modulation of catalyst film thickness may lead to production of low-density, long MWCNTs. Generally, a thinner catalyst layer leads to lower-density, longer MWCNTs.

5. Adhesive Underlayer

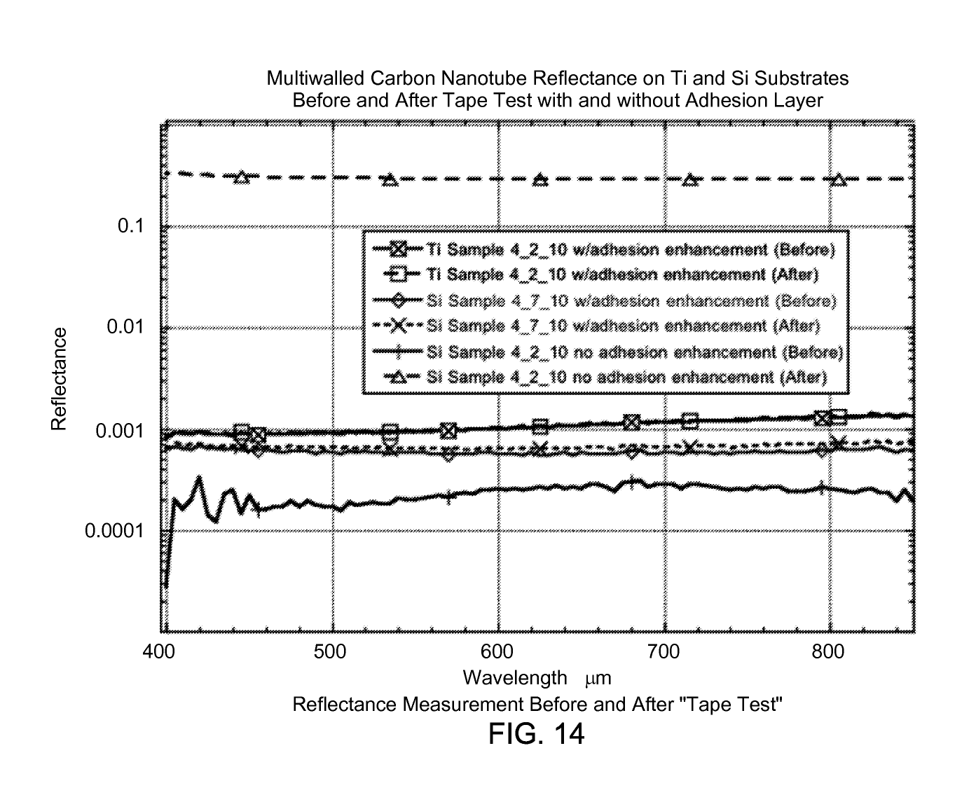

In order to grow MWCNTs that are robust enough to survive harsh environments such as launch conditions and space, an additional adhesive underlayer may be used under the catalyst layer to improve adhesion of the MWCNTs. When used as an adhesive underlayer, alumina provides strong adhesion of the MWCNTs that does not significantly degrade the optical properties of MWCNTs noted above. FIG. 14 illustrates reflectance measurements on samples of enhanced adhesion MWCNTs grown on titanium substrates with adhesive underlayers and silicon substrates with and without adhesive underlayers both before and after a “tape test.” A tape test, such as the one employed during data collection for FIG. 14, may involve the application of standard office supply tape onto an enhanced adhesion MWCNT growth, followed by the removal of the tape. The removed tape may then be examined in order to determine the amount of MWCNTs removed from the substrate. Furthermore, reflectance measurements may be made to quantitatively determine the impact of the tape test on the light absorption capabilities of the MWCNTs. This graph indicates that the reflectance values for enhanced adhesion MWCNTs on titanium are only slightly changed by the impact of the tape test. This slight change is illustrated by the data plot for “Ti Sample 4_{—}2_{—}10 w/adhesion enhancement (Before)” (wherein “Before” refers to a measurement before the tape test occurs) compared to the almost identical values for the data plot “Ti Sample 4_{—}2_{—}10 wi/adhesion enhancement (After)” (wherein “After” refers to a measurement after the tape test occurs).

6. MWCNT Geometry

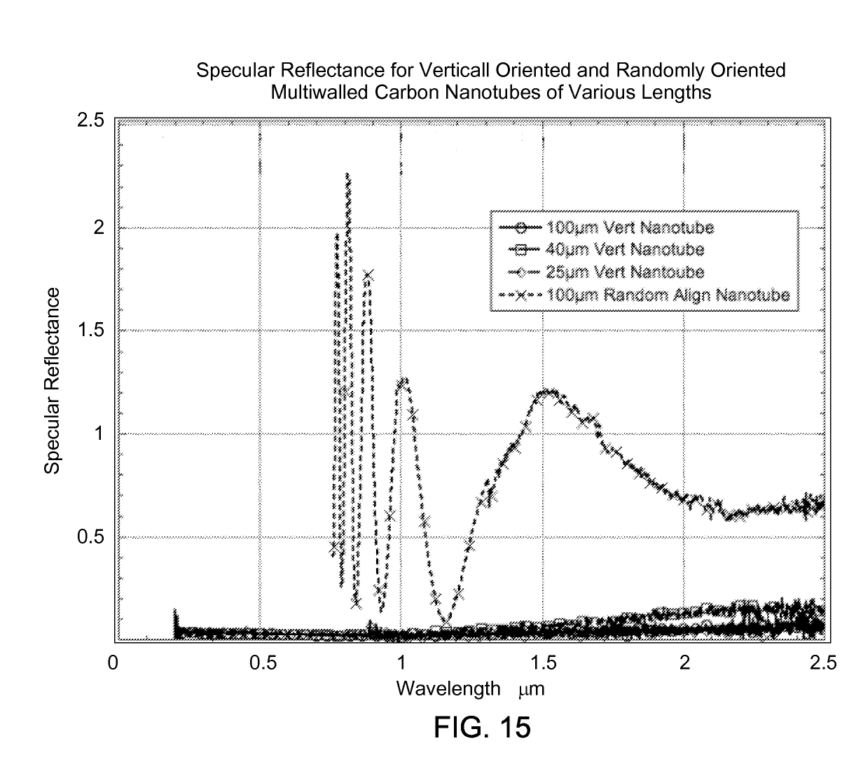

In order to achieve high light absorbing performance, long length (i.e., MWCNTs with a large length to diameter ratio) and low density MWCNTs (i.e., relatively large distances between individual MWCNTs) are desired. A preferred embodiment is MWCNTs with a length of 50-100 microns and average spacing of 100-500 nanometers, as this geometry provided optimal performance. In addition, near-vertical alignment of the MWCNT growth provides superior performance over MWCNTs with similar dimensions but grown in a randomized geometry. In testing, MWCNTS with inner- and outer-diameters at 1-5 nanometers and lengths of 30-100 nanometers respectively provided significant light absorbing capabilities. FIG. 15 compares specular reflectance data for light striking at an angle of incidence at eight degrees for randomly oriented MWCNTs (labeled “Random Align Nanotube”) and vertically oriented MWCNTs of varying lengths. Note that the vertically aligned nanotubes are significantly darker than the randomly oriented sample of similar diameter. In addition, the vertically aligned samples that are not as long are darker because of lower nanotube density, demonstrating the desire to optimize diameter, length, orientation and density.

7. Oxygen (O₂) Plasma Etching

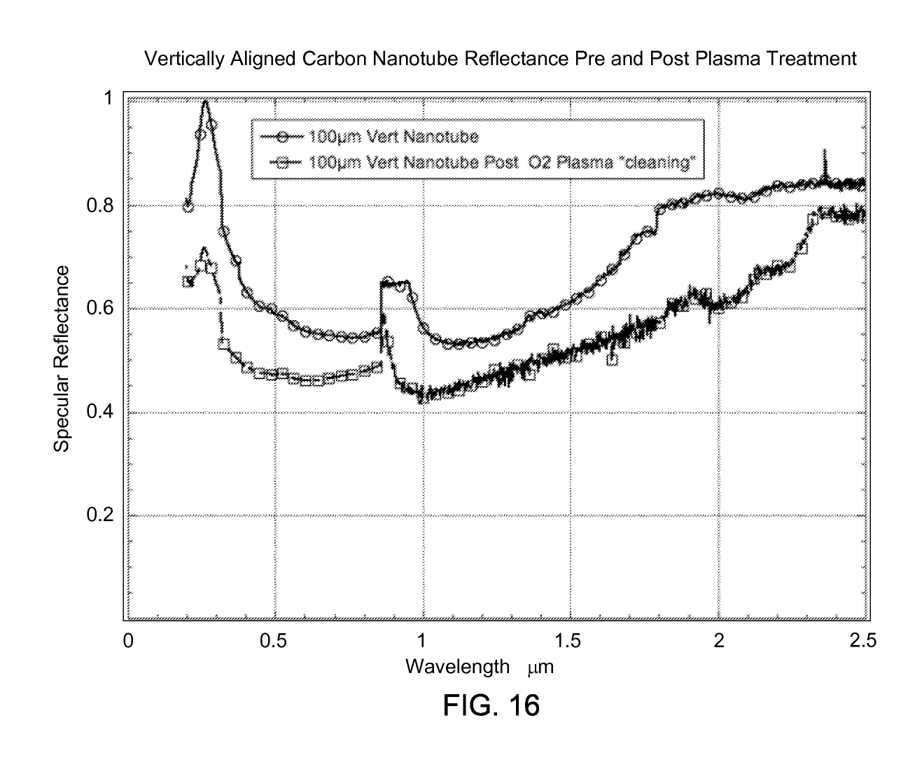

Using oxygen (O₂) plasma to etch the MWCNT film may increase the roughness and porosity of the MWCNT film, which may yield enhanced light absorptivity of approximately 20% over unetched film. FIG. 16 compares hemispherical reflectance of MWCNTs that have and have not undergone plasma oxidation.

8. Apodization. Mask of MWCNTs

Nanotubes may be grown to desired patterns by using lithographic masks to control the areas of catalyst deposition. This makes it possible to further reduce stray light by forming or growing the MWCNT mask in a particular shape that minimizes diffraction of light, as opposed to using a simple geometric shape. An apodization mask is a precise pattern or shape that is mathematically derived using light scattering measurement techniques to achieve optimal light absorption. By way of example and not limitation, an exemplary six petal hyper-gaussian shape provided eight orders of magnitude of stray light suppression in the zone of interest in testing.

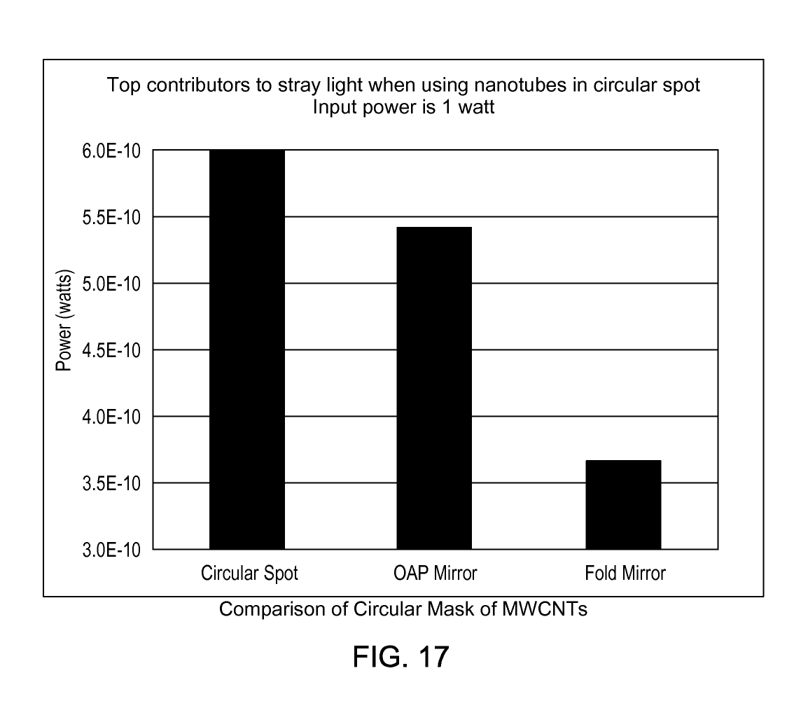

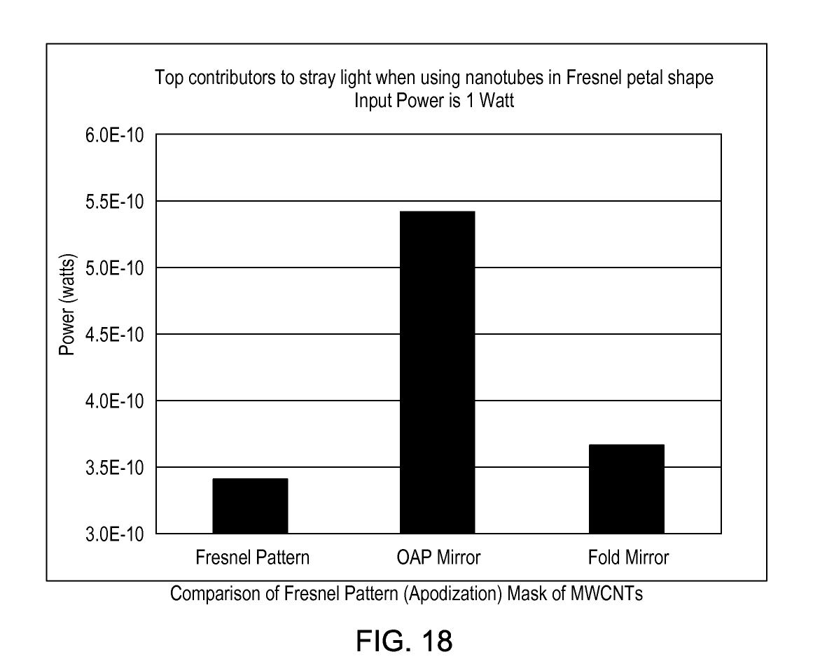

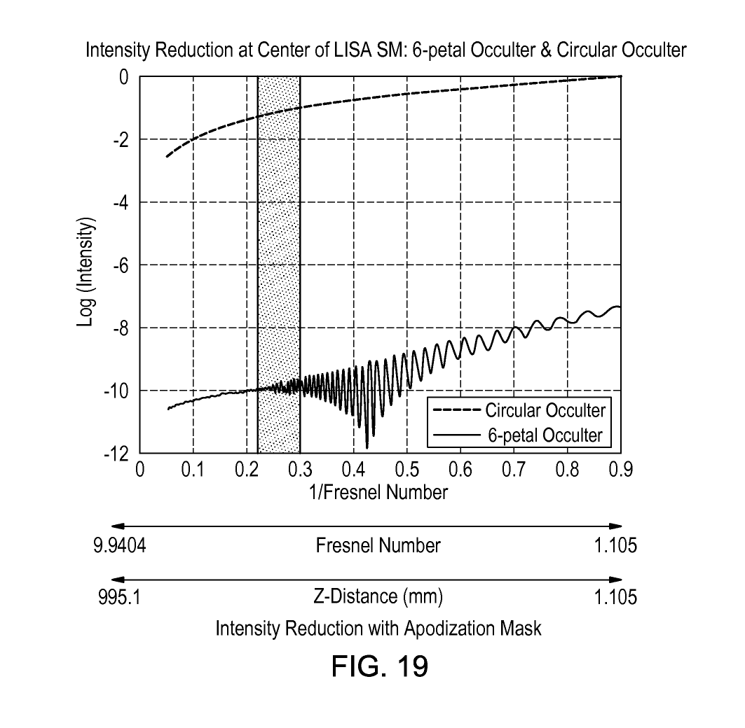

Both FIGS. 16 and 17 compare stray transmitter laser reflectance values from common duplex telescope components and a light absorbing solution used on the secondary mirror of a duplex telescope. FIG. 17 shows the contribution of stray light from a circular MWCNT mask (labeled “circular spot”), an off-axis parabolic (OAP) mirror and a fold mirror. By way of example and not limitation, an apodization mask in the form of an exemplary six petal hyper-gaussian shape (labeled “Fresnel pattern”) was used in FIG. 18. FIG. 18 shows the stray light contribution from an apodization mask of MWCNTs in an example Fresnel pattern against the same OAP Mirror and Fold Mirror used in FIG. 16 for comparison. Due to the high incident power of the telescope laser transmitter, even the circular MWCNT mask in FIG. 17 resulted in stray light contribution from the secondary mirror being the highest source of stray light. However, using the exemplary hyper-gaussian shape in FIG. 18, the contribution to stray light from the secondary mirror after the apodization mask is applied is reduced by a factor of 2, making it the smallest of the top 3 contributors to stray light. FIG. 19 illustrates intensity reduction with respect to Fresnel number and compares both a circular mask versus an apodization mask.

### D. Other Potential Uses of the Invention

1. Remote Sensing

Improved radiometric and spatial performance of remote sensing instruments afforded by MWCNT technology could contribute to the retrieval of sea surface temperature, particularly in tropical regions where cold clouds often form over warm oceans. Other areas of remote sensing science which could directly benefit include the determination of sea ice extent and the collapse of major ice sheets, snowfall cover, and fire detection.

Satellite remote sensing of ocean color/chlorophyll is one of the most radiometrically challenging and climate-sensitive Earth science measurements that may be made. The Earth's oceans are an optically dark target in the visible and near infrared and often dotted with numerous bright clouds. It is globally sensed by NASA's SeaWiFS and MODIS instruments approximately every two days. However, approximately one week is required to obtain a complete global ocean sampling from these instruments due to cloud cover of the ocean. Improvements in near and far-field stray light performance realized through the use of MWCNTs on instrument optical and stray light surfaces may increase the number of chlorophyll retrievable pixels by 32%. Elements typically used in optical devices to control stray light, including but not limited to, mirrors, apertures, baffles, vanes, and scan cavities, may also benefit from the use of MWCNTs. Such use constitutes a significant improvement in global coverage for the study of ocean color/chlorophyll. Improved spatial and radiometric performance realized by the application of MWCNT technology may also improve the ability to perform science in coastal zones and in captured bodies of water, such as the Chesapeake Bay.

2. Electron Emission Technology

It should also be noted that MWCNTs have been used in electron emission technology, for charge balancing colloid particle micro Newton ion thrusters, and have been space flight qualified for the NASA/ESA NEW Millennium Program, ST-7/SMART-2 mission.

3. Infrared Detection and Thermal Sensing

Enhanced adhesion MWCNTs on silicon nitride substrates may be used as a replacement for gold black thermal detectors in far-infrared and mid-infrared detection. Such MWCNTs may absorb light from all angles and may significantly improve the coupling of radiation to an infrared detector, alleviating the need for a cavity typically used in Winston Cone (conic parabolic) concentrators.

4. Other Potential Sensor Uses

Other potential uses for MWCNTs in sensing exist. MWCNTs may also be grown directly on a chip as (1) an integrated biosensor for use in detection of chemicals, and (2) as a strain gauge or pressure transducer for measuring strain and pressure respectively.

### E. Benefits of the Invention

Using a MWCNT apodization mask may allow for the absorption of stray, unwanted transmitter light from entering the receiver. There are multiple benefits associated with this innovation, namely: (1) simplification of instrument stray light controls without sacrificing performance; (2) increasing observational efficiencies by recovering currently unusable scenes in high contrast regions; and, (3) enabling low-noise observations that are beyond current capabilities.

1. Benefits of MWCNTs Over Black Paint for General Stray Light Suppression

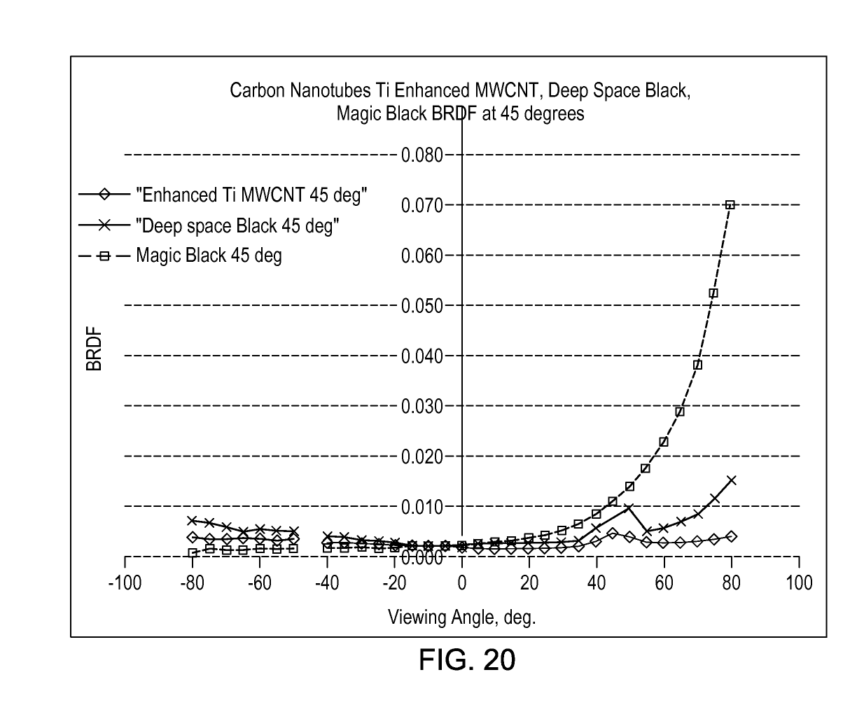

One skilled in the art will recognize that the problem of stray light interference has historically been compensated through the application of black paint on reflective areas. FIGS. 11, 12 and 13 show light absorption performance of MWCNTs against Z306, and FIG. 20 shows a BRDF of MWCNTs against Deep Space Black and Magic Black.

In scattered light measurement testing, the MWCNT apodization mask outperformed Z306 at an eleven-fold improvement. A representative NASA observatory was modeled including a telescope imaging instrument and associated optics and detector. The model included normal stray light controls which are typically treated with black paint. When MWCNTs were used in place of black paint, a Total Integrated Scatter measurement revealed an improvement in system stray light by a factor of 10,000, resulting in a factor of ten improvement in hemispherical reflectance. This measurement includes the further attenuation of stray light achieved during multiple bounces, i.e., the ricocheting of light within the instrument.

2. Benefits of MWCNTs Over Cutting a Hole Into the Secondary Mirror for Stray Light Suppression

One skilled in the art will also be familiar with the problems that are introduced with the alternative solution of simply cutting a hole in the secondary mirror to allow some transmitted light to escape. However, several problems are introduced by cutting a hole in the secondary mirror, including but not limited to, spalling, unacceptable structural weaknesses in the secondary mirror resulting from the hole causing the mirror to crack, and introduction of spurious light from other light emitting bodies such as the sun. In testing, MWCNTs were half as effective in compensation for stray light than using a hole in the secondary mirror when the total irradiance reaching the detector is calculated, however this measurement was performed without calculating for spurious light through a hole in from the other side of the mirror. Such spurious light from outside sources will likely cause more interference at the receiver than using no light absorption solution at all.

### F. Detailed Description of the Drawings

Additional features and advantages of the disclosure will be set forth in the description which follows, and in part will be obvious from the description, or may be learned by practice of the herein disclosed principles. The features and advantages of the disclosure may be realized and obtained by means of the instruments and combinations particularly pointed out in the appended claims. These and other features of the disclosure will become more fully apparent from the following description and appended claims, or may be learned by the practice of the principles set forth herein.

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

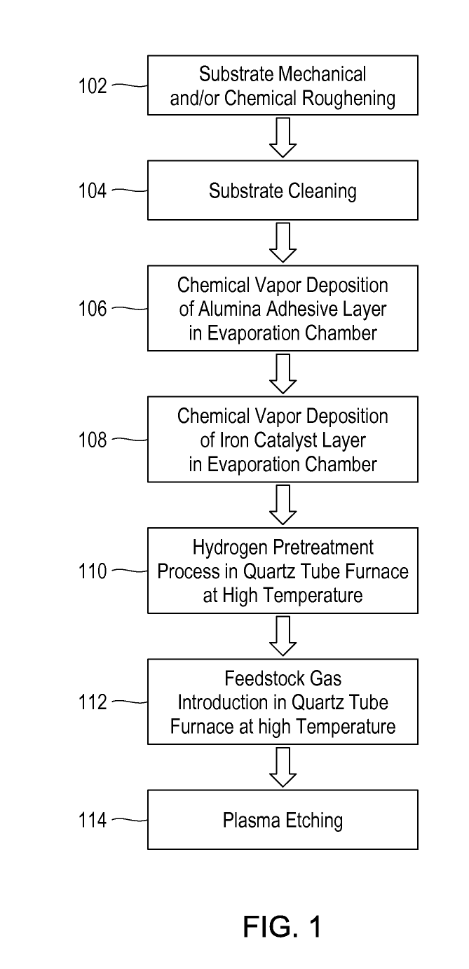

1. FIG. 1

FIG. 1 illustrates an exemplary method embodiment for growth of enhanced adhesion MWCNTs on a titanium substrate, the method comprising: substrate mechanical and/or chemical roughening 102; standard solvent cleaning of the substrate 104; chemical vapor deposition of an adhesive underlayer composed of alumina on a substrate composed of titanium 106; chemical vapor deposition of an catalyst composed of a thin film of iron on top of the adhesive underlayer 108; pretreatment of the substrate to hydrogen at high temperature 110; and exposure of the substrate to a feedstock gas composed of ethylene at high temperature 112; and plasma etching of the MWCNT film 114. This method of growth allows for high strength adhesion of MWCNTs to the substrate the MWCNTs are grown upon. The enhanced adhesion MWCNTs resulting from the method have a significant light absorbing capability when grown on structural substrates such titanium and stainless steel, or for silicon nitride, useful in detector applications.

This method of growth allows for high strength adhesion of MWCNTs to the substrate the MWCNTs are grown upon. The enhanced adhesion MWCNTs resulting from the method have a significant light absorbing capability when grown on structural substrates such titanium and stainless steel, or for silicon nitride, useful in detector applications.

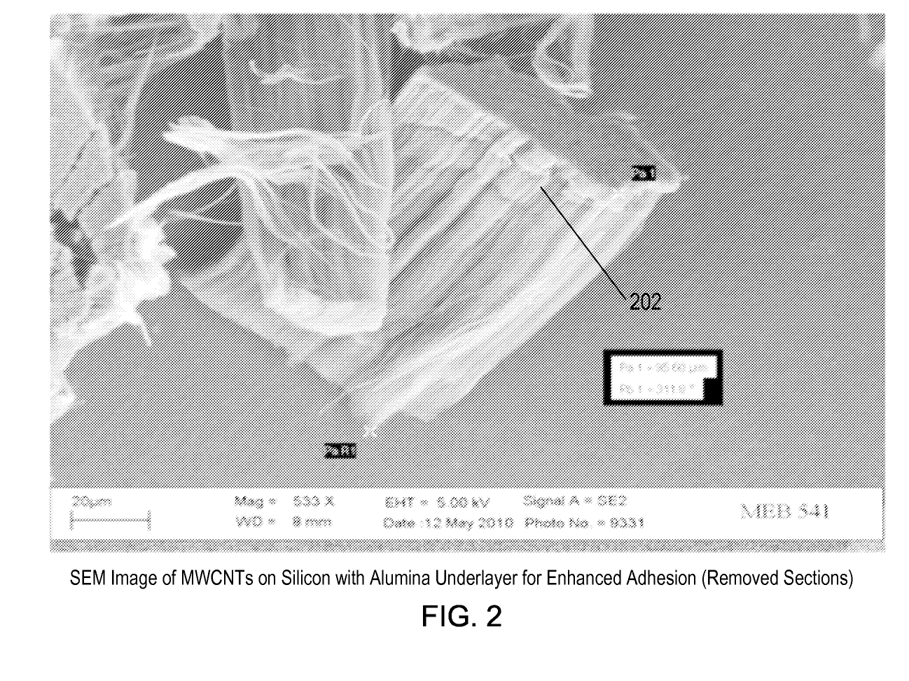

2. FIG. 2

MWCNTs grown on silicon with only the iron catalyst layer generally exhibit poor adhesion; such a film of MWCNTs may be damaged or destroyed with minimal contact. Utilization of MWCNTs in space flight hardware often requires alumina, when used as an underlayer between the catalyst layer and substrate, may provide improved adhesion between MWCNTs and the substrate upon which the MWCNTs are grown without significantly degrading the optical properties of the MWCNTs. FIG. 2, is a scanning electron microscope (SEM) image of a section of MWCNT film 202 that was physically removed to allow inspection. In general the film is uniform, oriented and quite robust to physical contact.

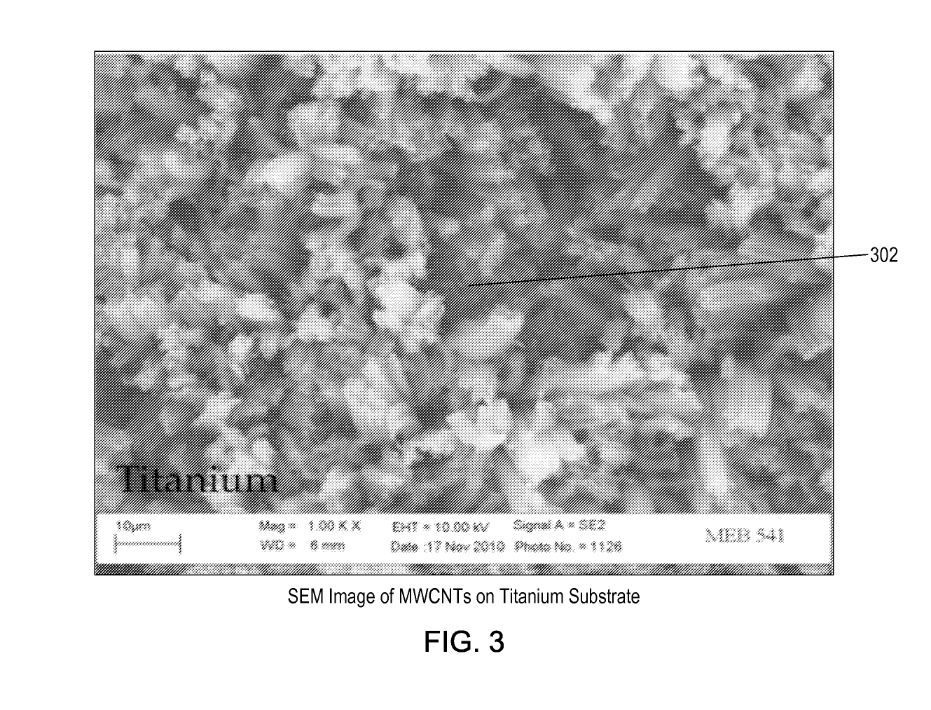

3. FIG. 3

While silicon generally yields an excellent light-absorptive ability when used as a substrate to grow MWCNTs on, silicon is quite brittle and is not the material of choice for elements that may be subjected to structural loads. To address the need for nanotube growth on materials more suitable for load bearing, titanium may be used as a substrate. Titanium is more suited to use as a structural element that also allows for growth of MWCNT film 302 which retains a comparable light-absorptive ability to the use of a silicon substrate. FIG. 3 is a SEM image of growth on titanium.

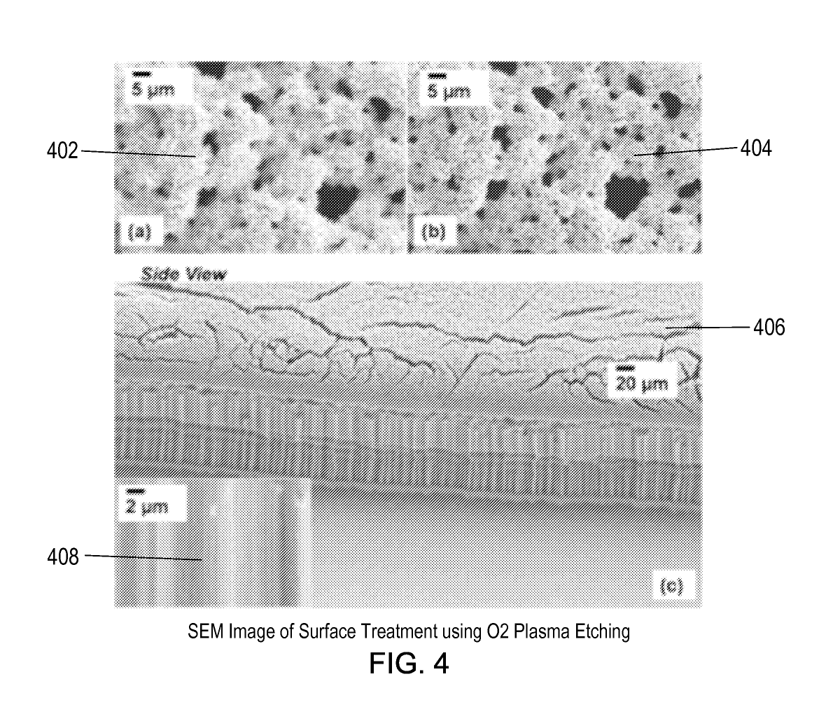

4. FIG. 4

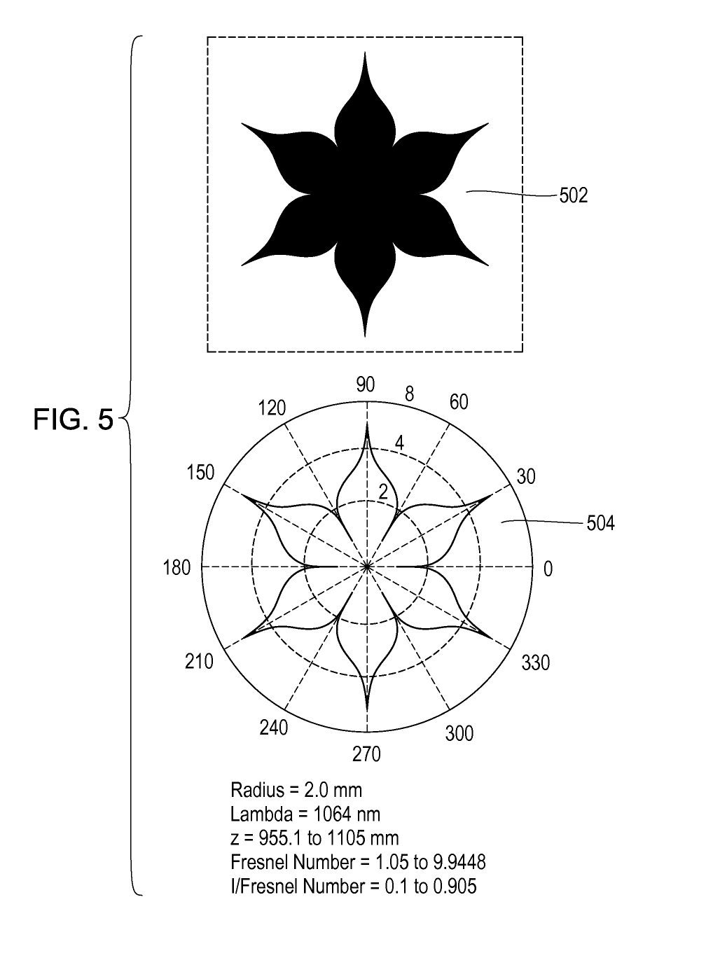

Using oxygen (O₂) plasma to etch the surface of the of the MWCNT film may increase the roughness and porosity of the MWCNT film, yielding enhanced light absorptivity. An SEM image of plasma treated MWCNT film 402, 404, 406 and 408 is shown in FIG. 5

MWCNTs may be grown to desired patterns by using lithographic masks to control the areas of deposition. This makes it possible to further reduce the stray light in the LISA telescope by moving from, by way of example and not limitation, a circular shaped mask to a shape that minimizes diffraction. Diffraction codes used for stellar occulting systems used at NASA yielded an optimal shape for the carbon nanotube patch on the secondary mirror in the form of a hyper-gaussian shape 502, 504 resembling the petals on a flower. By way of example and not limitation, an exemplary six petal hyper-gaussian shape is shown in FIG. 5.

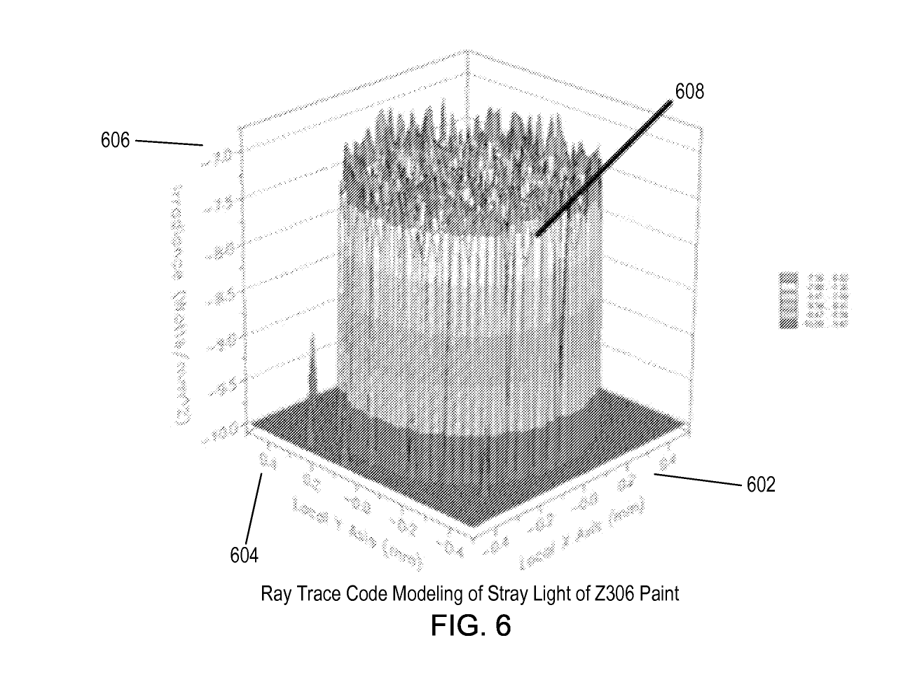

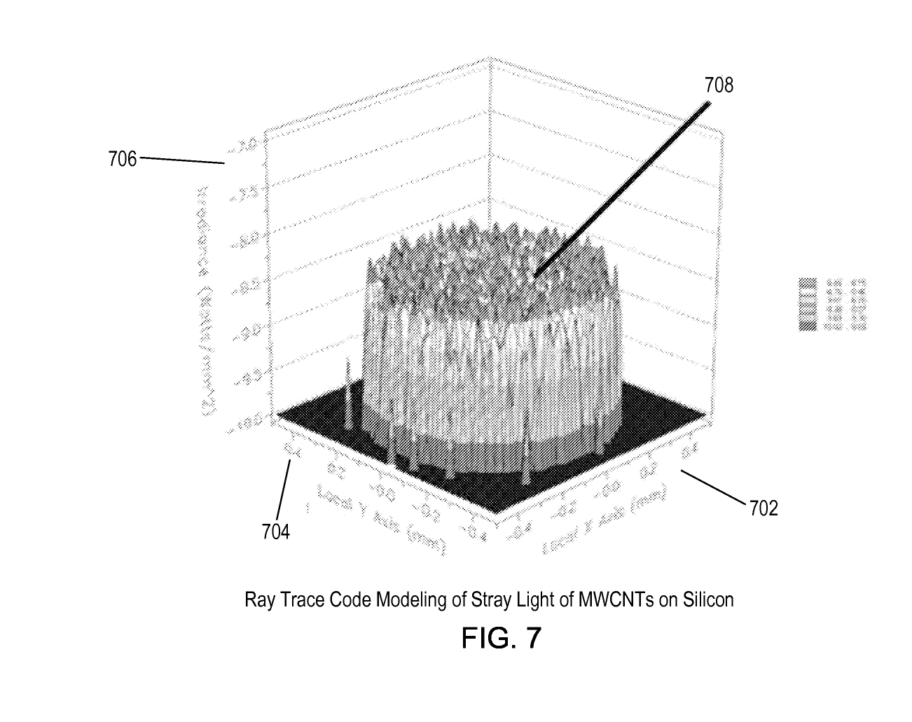

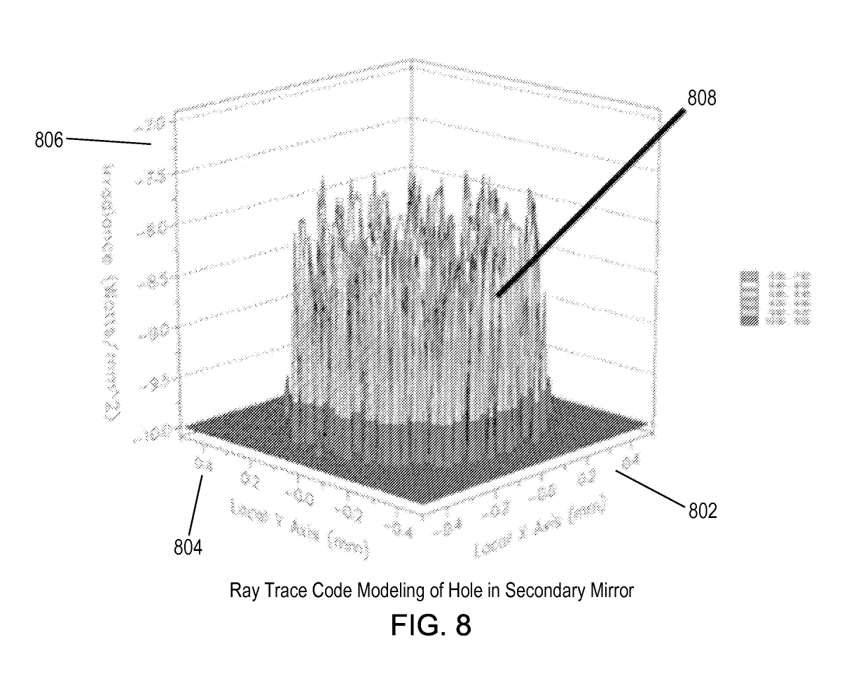

5. FIGS. 6, 7 and 8

Using a ray trace code may model end to end optical systems and evaluate image quality, ghosting and stray light. FIGS. 6, 7 and 8 show a ray trace code modeling of three light-absorbing solutions: a circular patch of Z306 paint, an apodization mask of MWCNTs and a hole cut into the secondary mirror 1006 respectively. The X Axis 602, 702 and 802 show the length of one side of the sample in millimeters for each Z306, MWCNTs and a hole in the secondary mirror 1006, respectively. The Y Axis 604, 704 and 804 show the length of the side opposing the X Axis of the sample in millimeters for each Z306, MWCNTs and a hole in the secondary mirror 1006 respectively. The Z Axis 606 706 and 806 displays values in watts per millimeter squared of irradiance. The irradiance values 608, 708 and 808 show the irradiance measurements based on noise from stray light taken from BRDF data from each sample of Z306, MWCNTs and a hole in the secondary mirror 1006 respectively.

The graphs reveal that carbon nanotube patch is a factor of 11 better than the Z306 paint, but a factor of 2 worse than the hole in the secondary mirror 1006 when the total irradiance reaching the detector is calculated. This calculation however does not take into account the implementation of beam dump behind the hole (since an open hole would provide a direct stray light path from other sources, such as bright stars) or the additional problems that may be introduced in fabricating a hole in the secondary mirror 1006. With such a hole in the secondary mirror 1006, the photodetector 1012 may be directly exposed to light in front of the telescope (such as stars and other bright objects), likely creating more interference than would be avoided by using a hole. In addition, when peak irradiance is evaluated the nanotubes provide a more uniform background than the hole.

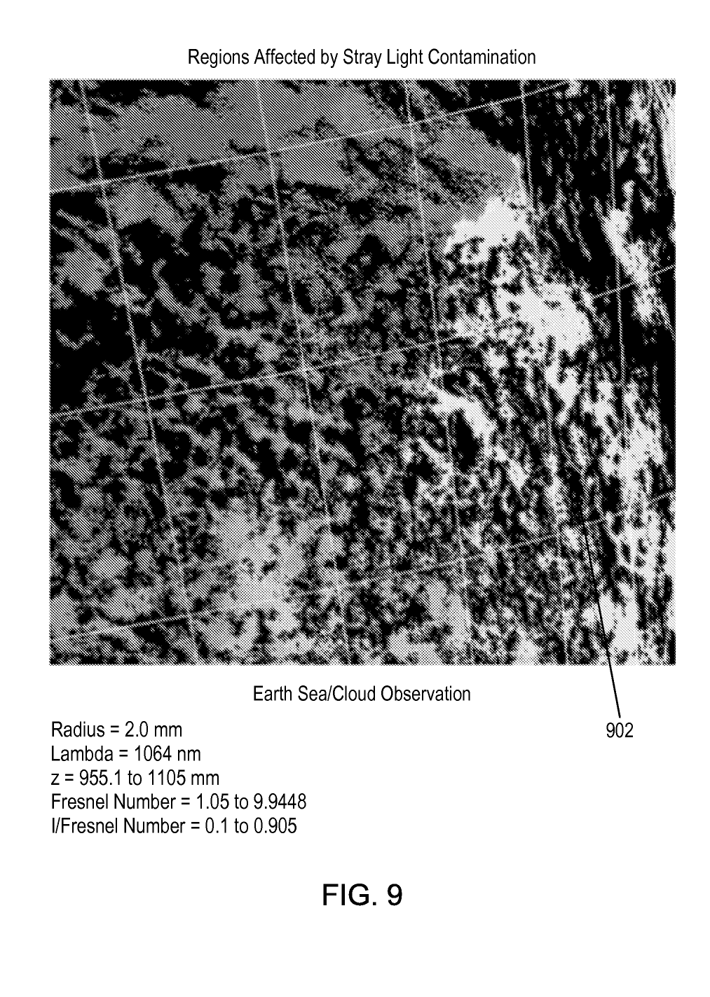

6. FIG. 9

The Earth's oceans are an optically dark target in the visible and near infrared and often dotted with numerous bright clouds, As shown in FIG. 9 improvements in near and far-field stray light performance 902 realized through the use of MWCNTs on instrument optical and stray light surfaces may increase the number of chlorophyll retrievable pixels by 32%. This constitutes a significant improvement in global coverage for the study of ocean color/chlorophyll. Improved spatial and radiometric performance realized by the application of MWCNT technology will also improve the ability to perform science in coastal zones and in captured bodies of water, such as the Chesapeake Bay.

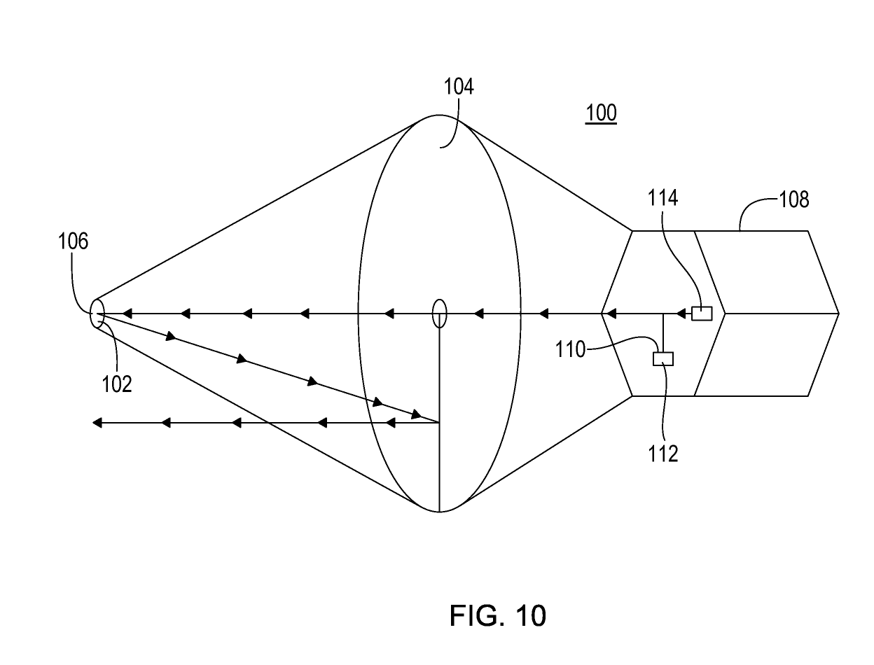

7. FIG. 10

The system configuration shown herein is exemplary and involves multiple elements. Other systems may include a larger or smaller number of elements in numerous other configurations, including arrays of discrete telescopes. Other methods of transmission include other frequencies of electromagnetic radiation.

a. Signal Reception

In the example shown in FIG. 10, the telescope 1000 receives a laser coaxially with the emitted laser, which is first collected by primary mirror 1004 and focused onto secondary mirror 1006. The laser is then focused further through an aperture in the primary mirror 1004 onto the focal surface 1010 of the photodetector 1012 within the aft optics 1008 of the telescope 1000.

b. Signal Transmission

In this example, a laser is emitted from the transmitter 1014 in aft optics 1008 coaxial with the received laser. The laser is transmitted through the aperture in the primary mirror 1004 onto the secondary mirror 1006, which defocuses the beam onto the primary mirror 1004 which collimates the beam for transmission.

c. Interference of Transmitted and Received Signals

The problem created by duplexing is that the transmitted signal is nearly on axis to the center of the secondary mirror 1006 which may cause transmitted light to reflect back onto the focal surface 1010 of the receiving photodetector 1012. The transmitted beam may be many orders of magnitude higher in intensity and may need to be suppressed due to the overwhelming interference.

d. Apodization Mask

An apodization mask of MWCNTs 1002 may be affixed, grown or applied to the affected area of the secondary minor 1006 to absorb light emitted from the transmitter 1014 from diffracting back onto the focal surface 1010 of the receiving photodetector 1012. An apodization mask composed of MWCNTs may compensate for stray light at an multi-fold improvement over a mask using flat black paint. Such an apodization mask may avoid problems generated by creating a hole in the secondary mirror 1006. Cutting a hole into the secondary mirror 1006 may introduce additional problems. Examples of problems include the introduction of spurious light from other sources such as astronomical bodies which may then enter receiver, and the additional engineering challenges involved in cutting a hole into a secondary mirror 1006 without compromising structural integrity or optical quality of the secondary mirror 1006. Using an apodization mask may also provide a more uniform background than a hole as well as avoiding the aforementioned problems.

The preceding is written for illustration pursuant to 35 USC §112 for disclosing the best mode currently contemplated by the inventors. While specific implementations are discussed, it should be understood that this is done for illustration purposes only. A person skilled in the relevant art will recognize that other components and configurations may be used without parting from the spirit and scope of the disclosure.

What is claimed is:

1. A method of growth of enhanced adhesion multi-walled carbon nanotubes on a substrate, the method comprising:
(a) depositing by a chemical vapor an adhesive layer on the substrate;
(b) depositing by a chemical vapor a catalyst film on the adhesive layer;
(c) pretreating the substrate with hydrogen gas; and
(d) exposing the substrate to a feedstock gas.

2. The method of claim 1 further comprising the step of cleaning the substrate prior to the steps of depositing by chemical vapor.

3. The method of claim 2 wherein the cleaning is accomplished with a solution of acetone.

4. The method of claim 2 wherein the cleaning is accomplished with a solution of isopropanol.

5. The method of claim 2 wherein the cleaning is accomplished with a solution of ethanol.

6. The method of claim 2 wherein the cleaning is accomplished with a solution of water.

7. The method of claim 2 further comprising the step of roughening the substrate prior to the step of cleaning.

8. The method of claim 7 wherein the step of roughening the substrate is accomplished through mechanical grinding.

9. The method of claim 7 wherein the step of roughening the substrate is accomplished through chemical etching.

10. The method of claim 1 further comprising the step of plasma etching the multiwalled carbon nanotubes after the step of exposing the substrate to a feedstock gas.

11. The method of claim 10 wherein plasma etching is accomplished with oxygen plasma.

12. The method of claim 1 wherein the substrate is composed of titanium.

13. The method of claim 1 wherein the substrate is composed of stainless steel.

14. The method of claim 1 wherein the substrate is composed of silicon nitride.

15. The method of claim 1 wherein the substrate is composed of silicon.

16. The method of claim 1 wherein the adhesive layer is composed of alumina.

17. The method of claim 1 wherein the catalyst layer is composed of iron.

18. The method of claim 1 wherein the feedstock gas is composed of ethylene.

19. Enhanced adhesion multiwalled carbon nanotubes on a substrate, wherein the multiwalled carbon nanotubes are grown by depositing an adhesive layer and a catalyst by chemical vapor on the substrate; pretreating the substrate with hydrogen; and exposing the substrate to a feedstock gas.
